(19) United States
(12) Patent Application Publication
(10) Pub. No.: US 2004/0245538 A1
(43) Pub. Date: Dec. 9, 2004

(54) Double sided optoelectronic integrated circuit

(76) Inventors: Xiaolin Wang, San Jose, CA (US); Mahmood Toofan, Milpitas, CA (US); Yi Ding, Milpitas, CA (US)

Correspondence Address: Timothy N. Trop,, TROP, PRUNER & HU, P.C., STE 100, 8554 KATY FWY, HOUSTON, TX, 77024-1841, US

(21) Appl. No.: 10/455,852

(22) Filed: Jun. 6, 2003

(51) Int. Cl. H01L 33/00; H01L 31/00

(52) U.S. Cl. 257/98; 250/214.1

(57) ABSTRACT

A single integrated wafer may be formed with optical components on one side and electronic components on the opposite side. Communication between the sides may be by way of optical signals that may be transmitted through the semiconductor wafer.

### BACKGROUND

This invention relates generally to integrated circuits and, particularly, to integrated circuits with applications in both optics and electronics.

Optoelectronic line cards may be made from discrete optical and electronic chips on either or both sides of a printed circuit board. The various chips may be coupled by printed circuits and optical fibers. These systems tend to be bulky and costly to manufacture and package, especially due to the manual fiber management or interconnection. The manufacturing yield and long term reliability of such products tends to be low.

Integration of optical and electronic devices for integrated circuits offers great potential for increasing the functionality of a single chip, greatly reducing manufacturing cost, improving yield and reliability of both electronic and optical systems and even increasing the performance through the reduction of parasitic effects. Optical electronic integrated circuit integration, however, has not been very successful to date. One difficulty may lie in the vast difference in the manufacturing requirements for electronic and optical devices. Many of the devices are either totally incompatible to monolithic manufacture of both optical and electronic devices on the same wafer or devices may suffer serious compromises in performance in order to be able to integrate both types of devices onto a single wafer.

Thus, there is a need for a better way to integrate both optical and electronic devices on the same wafer.

### BRIEF DESCRIPTION OF THE DRAWINGS

FIG. 1 is a greatly enlarged cross-sectional view of one embodiment of the present invention where the devices 12 are shown enlarged for illustration purposes;

FIG. 2 is an enlarged top plan view of another embodiment of the present invention;

FIG. 3 is a greatly enlarged cross-sectional view of another embodiment of the present invention; and

FIG. 4 is a greatly enlarged cross-sectional view of still another embodiment of the present invention.

### DETAILED DESCRIPTION

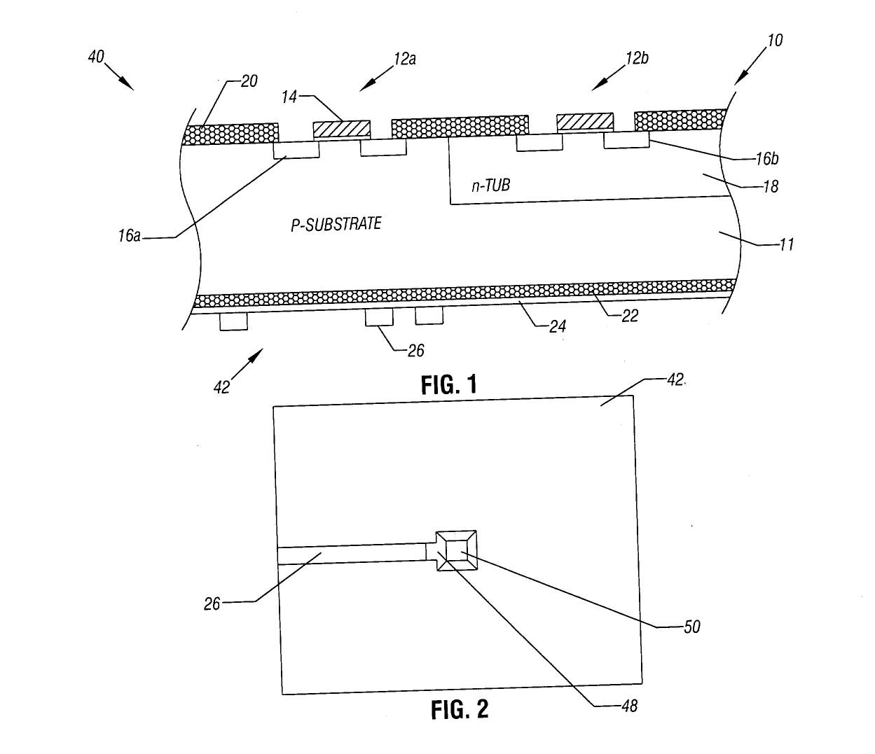

Referring to FIG. 1, an integrated circuit wafer or substrate 11 may have an electronics side 40 and an optics or backside 42. The electronics or top side 40 may be fabricated conventionally using a P-type substrate in one embodiment. A tub 18 may be formed in the substrate and source and drain regions 16a and 16b may be formed within the tub 18 and outside the tub 18 to create a complementary metal oxide semiconductor integrated circuit, including both an NMOS transistor 12a and PMOS transistor 12b. The transistors 12 may include gates 14. An oxide isolation layer 20 may be used as well. The details of the electronics side 40 described above are only exemplary and are not intended to be limiting of the scope of the invention.

On the opposite side 42 of the wafer or substrate 11, may be formed a buried oxide layer 22 in one embodiment. Over the layer 22 may be a silicon epitaxial layer 24 in what amounts to a silicon-over-insulator technology. Over the epitaxial layer 24 may be formed silicon-on-insulator ridges 26 to form waveguides for optical circuits. Again, the specific details of the optics side 42 are not intended to limit the scope of the invention.

Thus, the upper or electronics side 40 may be utilized for electronic devices and the lower or optics side 42 may be utilized for optical components. In other cases, the upper side 40 may be utilized for optical components and the lower side 42 may be used for electronic components.

Initially, devices may be separated into two groups according to their manufacturing characteristics. The two groups may be formed on the appropriate side 40 or 42 of a substrate on wafer 11. Two different process flows may then be applied to the two sides 40, 42 of the single wafer 11. As a result, compromises may be unnecessary in the manufacturing processes for the different technologies. The electronic and optical communication from one side to the other can be achieved through electronic and/or optical vias in some embodiments.

Instead of integrating optical and electronic devices on a single side of a wafer, the devices may be separated according to their manufacturing and isolation requirements into two groups. Fabrication flows may then be designed to achieve high performance for each respective group. The two groups of devices are then placed on the appropriate side of one wafer. In this way, fabrication flow compromises may be largely avoided.

While an illustration is given in FIG. 1 of a complementary metal oxide semiconductor technology on the side 40, bipolar devices may be formed as well. Waveguides may be formed on the side 42, as well as thermal optical switches and planar light circuits.

A silicon-on-insulator (SOI) or silica waveguide fabrication flow can then be applied to the backside 42 of the wafer 11. The electronic and optical communication between the front and back sides may be achieved by electronic and optical vias that can be made using silicon trenching in one embodiment.

The substrate 11 may be silicon or group III-V semiconductors, depending on the type of devices involved. The selection of the process flow may be based on how stringent are the requirements for the various devices.

In one embodiment, one may choose to first process the side 40 or 42 that requires the higher process temperature followed by the side 40 or 42 that requires lower process temperatures, to reduce the possible adverse impact on the temperature sensitive side. In some embodiments one side 40 or 42 may be processed to completion followed by processing of the opposite side. In other embodiments, processing may progress to a point on one side, switch to the other side and return thereafter to the first side. In some cases, the process flows may be engineered to enable processing of both sides at the same time. For example, thermal and deposition processing may be implemented simultaneously on both sides 40, 42. Dual sided processing may be implemented on edge supported wafers 11 in one embodiment.

Referring to FIG. 2, the optical side 42 may include a ridge waveguide 26 that is coupled to a rectangular trench 50 in one embodiment of the present invention. The trench 50 may have faceted reflective sidewalls 48, which reflect light transversely from the ridge waveguide 26 through the substrate 11 to the opposite, electronic or top side 40.

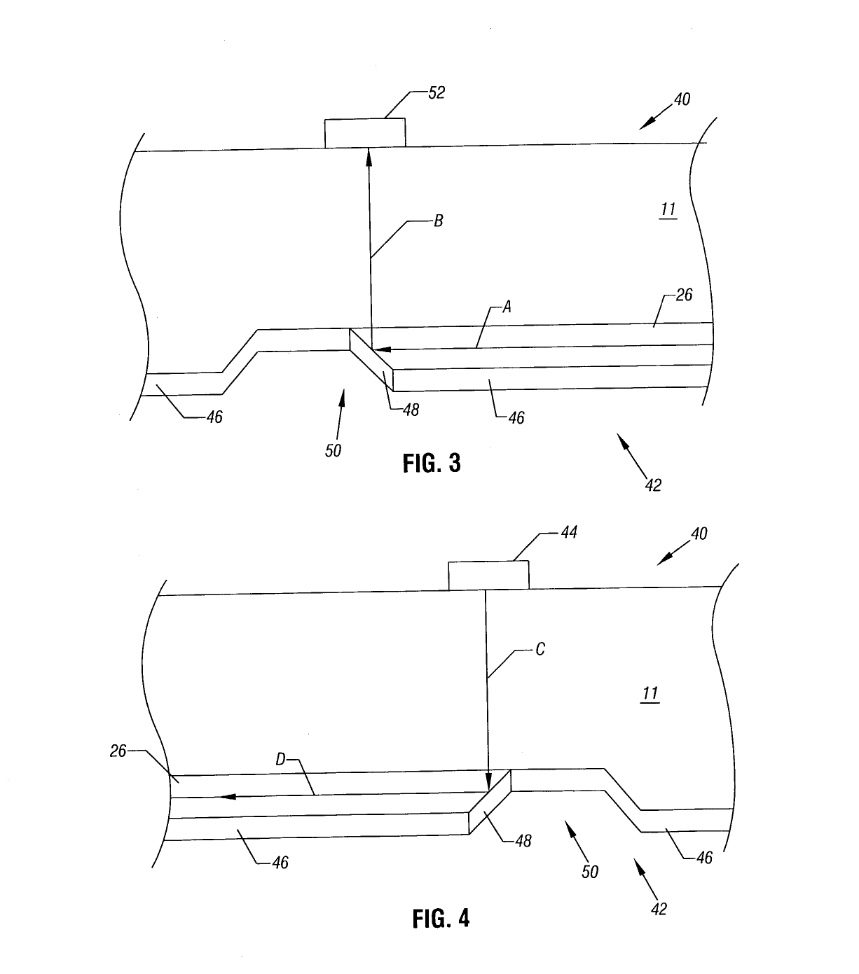

For example, referring to FIG. 3, the substrate 11 may have a photodetector 52 that converts optical energy received from the opposite side 42 into an electronic signal. That signal may then be processed on the electronics side 40. The photodetector 52 may be formed on the electronics side 40 of the wafer 11.

Light traveling through the ridge waveguide 26, indicated by the arrow A, may be reflected by the facet 48 of the trench 50, as indicated by the arrow B. The light signal B may travel through the optically transmissive substrate 11 to the photodetector 52 in one embodiment of the present invention.

The ridge 26 may be covered by an upper cladding 46. The upper cladding 46 may be formed by oxidation in one embodiment and the ridge waveguide 26 may be silicon in one embodiment. The facets 48 may be formed of oxide as well.

In one embodiment of the present invention, silicon-on-insulator technology may be utilized to form the ridge waveguides 26 and the cladding 46. A wet etch may be utilized on the waveguide 26. Since silicon is a crystal, relatively perfect 45 degree facets 48 may be formed easily with a wet etch using a silicon or other crystal waveguide 26. Due to the high refractive index of silicon-over-silicon dioxide, for example, total reflection may occur at the 45 degree mirror facet 48. The facet 48 may direct the light through the substrate 11 which, in one embodiment, may be formed of silicon, to the photodetector 52 on the opposite side of the wafer 11.

Referring to FIG. 4, a light signal from a light emitting diode or laser diode 44, on the electronics side 40, may pass through the substrate 11 as indicated by the arrow C. Light signal C may be reflected by the facet 48 on the optical side 42 of the wafer 11 in this case. As a result of the reflection from the facet 48, the light signal D may progress along a ridge waveguide 26 in one embodiment of the present invention. The signal D may then be optically processed by components on the optical side 42.

The facets 48 in the upper cladding 46 may be formed of oxide in one embodiment. Again, a trench 50 may be defined having the facet 48. The trench 50 may be aligned with the upper cladding 46 in one embodiment. Total reflection facets 48 can also be used for square core germanium doped waveguides or ridge waveguides of silicon nitride materials in other embodiments.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. An integrated circuit wafer comprising:
a first side having optical components formed thereon; and
a second side having electronic components formed thereon.

2. The wafer of claim 1 including optical components on the backside and electronic components on the top side of the wafer.

3. The wafer of claim 1 wherein said optical components are silicon components formed over an insulator.

4. The wafer of claim 1 including vias coupling said optical and electronic components.

5. The wafer of claim 1 wherein said wafer is sufficiently light transmissive to enable optical communications through said wafer.

6. The wafer of claim 1 including a photodetector on said second side.

7. The wafer of claim 1 including a photoemitter on said first side.

8. The wafer of claim 1 wherein said first side includes a waveguide, said waveguide coupled to an angled reflector to reflect light from said waveguide through said wafer.

9. The wafer of claim 1 including a waveguide on said first side, said waveguide including an angled surface to receive light transmitted through said wafer from said second side.

10. The wafer of claim 1 including a trench formed in said wafer, the sides of said trench being angled and acting as angled reflectors on said first side of said wafer.

11. The wafer of claim 10 wherein said trench sides are covered by an insulator.

12. An integrated circuit die comprising:
a first side having optical components formed thereon;
a second side having electronic components formed thereon; and
an optical path through said die from said first to said second side.

13. The circuit of claim 12 including optical components on the backside and electronic components on the top side of the die.

14. The circuit of claim 12 including a photodetector on said second side.

15. The circuit of claim 12 including a photoemitter on said first side.

16. The circuit of claim 12 wherein said first side includes a waveguide, said waveguide coupled to an angled reflector to reflect light from said waveguide through said die.

17. The circuit of claim 12 including a waveguide on said first side, said waveguide including an angled surface to receive light transmitted through said die from said second side.

18. The circuit of claim 12 including a trench formed in said die, the sides of said trench being angled and acting as angled reflectors on said first side of said die.

19. The circuit of claim 18 wherein said trench sides are covered by an insulator.

20. A method comprising:
forming optical components on a first side of an integrated circuit die;
forming electronic components on a second side of an integrated circuit die; and
enabling optical communications between said first and second sides through said die.

21. The method of claim 20 including providing more heat sensitive components on one side of said die and positioning less heat sensitive components on the other side of said die and processing said less heat sensitive components before said more heat sensitive components.

22. The method of claim 20 including forming a photodetector on said second side of said die.

23. The method of claim 20 including forming a photoemitter on the first side of said die.

24. The method of claim 20 including forming a waveguide on said first side of said die and forming an angled reflector to reflect light from said waveguide through said die.

25. The method of claim 20 including processing said first and second sides using independent process flows.

26. The method of claim 20 including interrupting the processing of one side of said die to process the other side of said die.

27. The method of claim 20 including performing a process step on both sides of said die at the same time.

28. The method of claim 20 including providing optical components on the backside of said die and electronic components on the front side of said die.

29. The method of claim 20 including communicating between said sides using a photoemitter on one side, a photodetector on the other side, and enabling light communication through said die between said photoemitter and photodetector.

30. The method of claim 20 including forming said die of a material that transmits an optical signal.
